(19) United States
(12) Patent Application Publication
(10) Pub. No.: US 2025/0022821 A1
(43) Pub. Date: Jan. 16, 2025

(54) SEMICONDUCTOR ELEMENT AND SEMICONDUCTOR DEVICE

(71) Applicant: ROHM CO., LTD., Kyoto-shi (JP)

(72) Inventor: Hirofumi TANAKA, Kyoto-shi (JP)

(21) Appl. No.: 18/898,031

(22) Filed: Sep. 26, 2024

Related U.S. Application Data
(63) Continuation of application No. PCT/JP2023/009607, filed on Mar. 13, 2023.

(30) Foreign Application Priority Data
Mar. 31, 2022 (JP) 2022-058712

(51) Int. Cl. H01L 23/00; H01L 23/495

(52) U.S. Cl. CPC H01L 24/05; H01L 23/49513; H01L 24/45; H01L 24/48; H01L 2224/05015; H01L 2224/05073; H01L 2224/05124; H01L 2224/05555; H01L 2224/05584; H01L 2224/05644; H01L 2224/05655; H01L 2224/05664; H01L 2224/45147; H01L 2224/48245; H01L 2224/48465; H01L 2924/3512

(57) ABSTRACT

A semiconductor element includes: an element body including an obverse surface facing a first side in a thickness direction z; a wiring layer formed on the obverse surface and electrically connected to the element body; an insulating layer covering the obverse surface and the wiring layer, and including a first opening through which the wiring layer is exposed; a surface protection film covering the insulating layer, and including a second opening through which the wiring layer is exposed; and a metal layer in contact with the wiring layer via the first opening and the second opening, and overlapping with the surface protection film as viewed in the thickness direction z. An outer edge of the metal layer is curved as viewed in the thickness direction z.

### TECHNICAL FIELD

The present disclosure relates to a semiconductor element and a semiconductor device.

### BACKGROUND ART

Semiconductor elements configured with switching circuits, such as metal-oxide-semiconductor field-effect transistors (MOSFETs) or insulated gate bipolar transistors (IGBTs), have been used for current control in various industrial apparatuses and vehicles. For example, JP-A-2020-77680 discloses an example of such a semiconductor element.

The semiconductor element includes a semiconductor substrate, a semiconductor layer, an interlayer insulating film, a wiring layer, a passivation film, an electrode, and a surface protection film. The semiconductor layer, the interlayer insulating film, the wiring layer, and the passivation film are formed on the semiconductor substrate, and the electrode, which is electrically connected to the wiring layer, is provided in a recess in the passivation film. The surface protection film covers the passivation film, and is formed with an opening that exposes the electrode. The wiring layer and the electrode contain Al. When a bonding wire containing Cu is bonded to the semiconductor element, the semiconductor layer may crack, or corrosion may occur at the boundary between the electrode and the bonding wire, causing a bonding failure of the bonding wire. To solve these problems, a semiconductor element has been developed in which a metal layer (including a Ni layer, for example) is formed instead of the electrode. The metal layer is in contact with the wiring layer and partially overlaps with a surface of the surface protection film, and is used as a pad for bonding the bonding wire.

### BRIEF DESCRIPTION OF THE DRAWINGS

FIG. 1 is a perspective view showing a semiconductor device according to a first embodiment of the present disclosure.

FIG. 2 is a plan view showing the semiconductor device of FIG. 1, as seen through a sealing resin.

FIG. 3 is a bottom view showing the semiconductor device of FIG. 1.

FIG. 4 is a front view showing the semiconductor device of FIG. 1.

FIG. 5 is a right-side view showing the semiconductor device of FIG. 1.

FIG. 6 is a cross-sectional view along line VI-VI in FIG. 2.

FIG. 7 is a cross-sectional view along line VII-VII in FIG. 2.

FIG. 8 is a plan view showing a semiconductor element according to the first embodiment.

FIG. 9 is a partially enlarged view of FIG. 8, showing a part around a metal layer.

FIG. 10 is a cross-sectional view along line X-X in FIG. 9.

FIG. 11 is a partially enlarged plan view showing a semiconductor element according to a second embodiment of the present disclosure.

FIG. 12 is a partially enlarged plan view showing a semiconductor element according to a third embodiment of the present disclosure.

FIG. 13 is a partially enlarged plan view showing a semiconductor element according to a fourth embodiment of the present disclosure.

FIG. 14 is a partially enlarged plan view showing a semiconductor element according to a fifth embodiment of the present disclosure.

FIG. 15 is a cross-sectional view along line XV-XV in FIG. 14.

FIG. 16 is a partially enlarged plan view showing a semiconductor element according to a sixth embodiment of the present disclosure.

### DETAILED DESCRIPTION OF EMBODIMENTS

The following describes preferred embodiments of a semiconductor element and a semiconductor device according to the present disclosure with reference to the drawings. In the following description, identical or similar elements are provided with the same reference numerals, and descriptions thereof are omitted. The terms such as “first”, “second” and “third” in the present disclosure are used merely as labels and not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “an object A (or the material thereof) contains a material C” includes “an object A (or the material thereof) is made of a material C” and “an object A (or the material thereof) is mainly composed of a material C”.

### First Embodiment

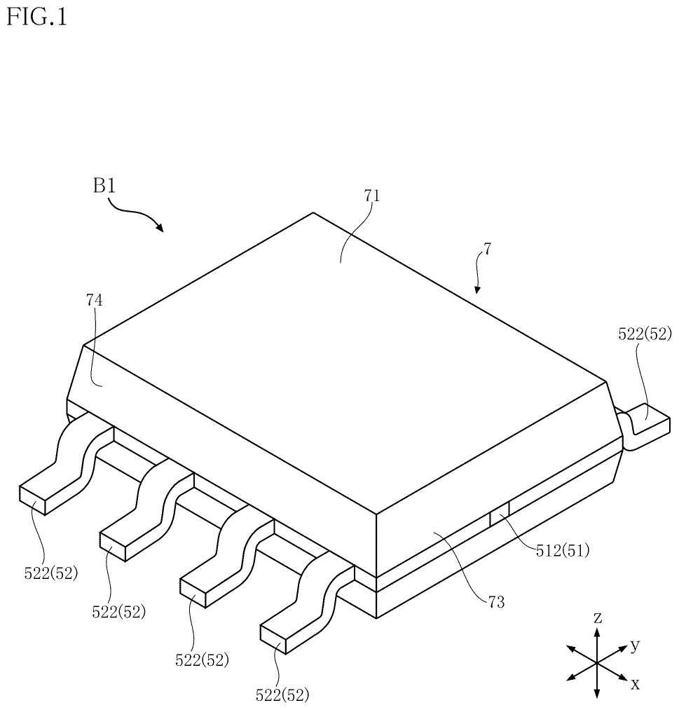

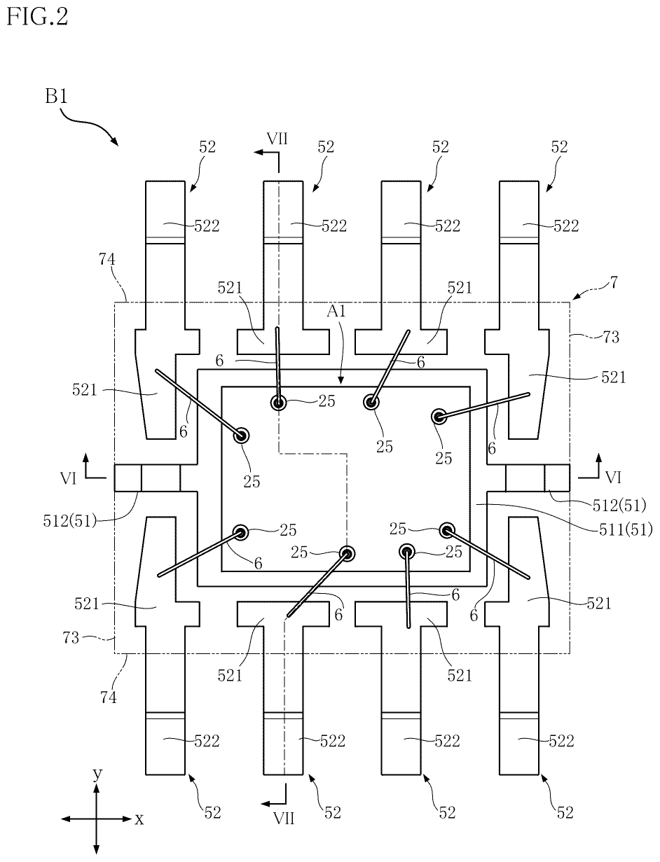

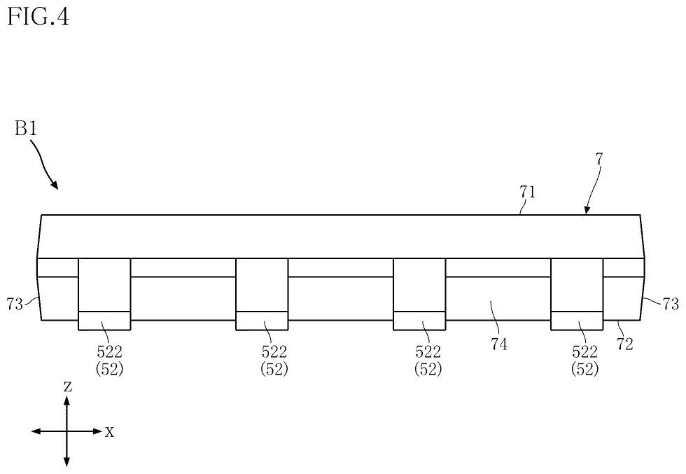

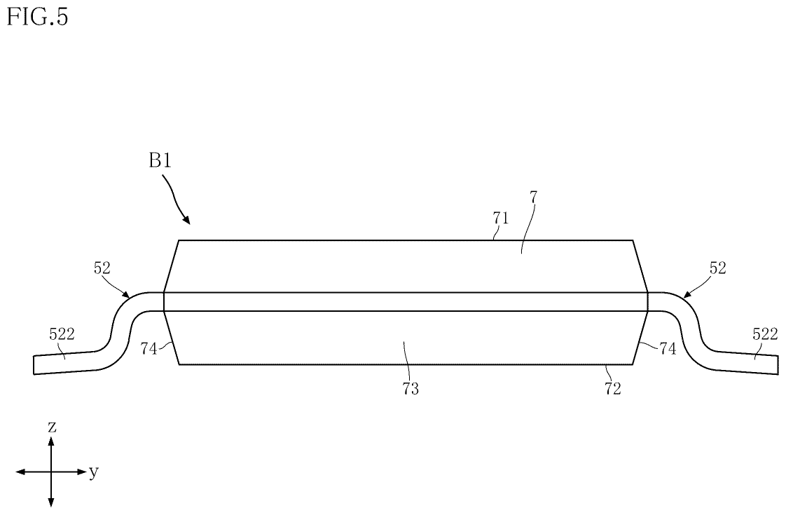

FIGS. 1 to 10 show a semiconductor element A1 according to a first embodiment and a semiconductor device B1 including the semiconductor element A1. For convenience of understanding, FIG. 2 shows a sealing resin 7 in phantom, and the outer shape of the sealing resin 7 is indicated by an imaginary line (two-dot chain line). As shown in these figures, the semiconductor device B1 includes the semiconductor element A1, a first lead 51, a plurality of second leads 52, a plurality of connecting members 6, and a sealing resin 7. The semiconductor device B1 is configured by modularizing the semiconductor element A1. The shape and size of the semiconductor device B1 are not particularly limited.

For convenience of description, the thickness direction of the semiconductor device B1 is referred to as “thickness direction z”. In the following description, one side in the thickness direction z may be referred to as “upward”, and the other side as “downward”. Note that the terms such as “top”, “bottom”, “upward”, “downward”, “upper surface”, and “lower surface” are used to indicate the relative positions of components or the like in the thickness direction z and do not necessarily define the relationship with respect to the direction of gravity. Also, “plan view” refers to the view seen in the thickness direction z. A direction perpendicular to the thickness direction z is referred to as “first direction x”. The first direction x is the horizontal direction in the plan view (see FIG. 2) of the semiconductor device B1. The direction perpendicular to the thickness direction z and the first direction x is referred to as “second direction y”. The second direction y is the vertical direction in the plan view (see FIG. 2) of the semiconductor device B1.

The semiconductor element A1 is an element that exerts an electrical function of the semiconductor device B1. In the present embodiment, the semiconductor element A1 is, for example, a bipolar CMOS DMOS (BiCDMOS) element, which is a semiconductor composite element in which a bipolar element, a complementary MOS (CMOS) transistor, and a double diffusion MOS (DMOS) transistor are formed on a common semiconductor substrate. Note that the semiconductor element A1 is not limited to a particular element.

As shown in FIGS. 2, 6 and 7, the semiconductor element A1 is mounted on the first lead 51. The semiconductor element A1 includes an element body 10, an insulating layer 13, a wiring layer 14, a reverse-surface electrode 24, a plurality of metal layers 25, and a surface protection film 26.

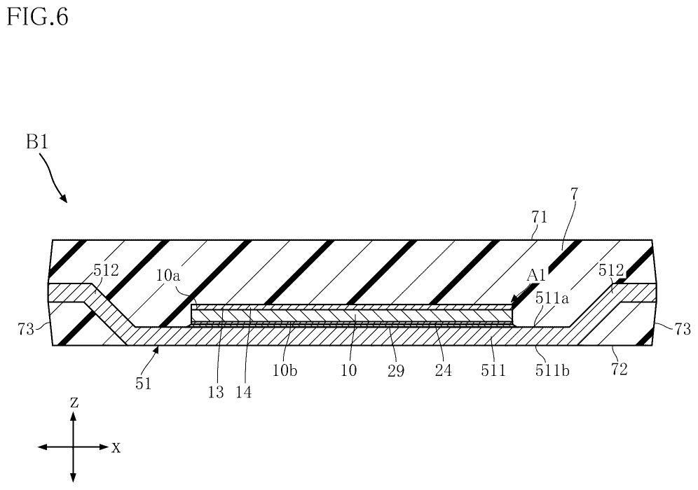

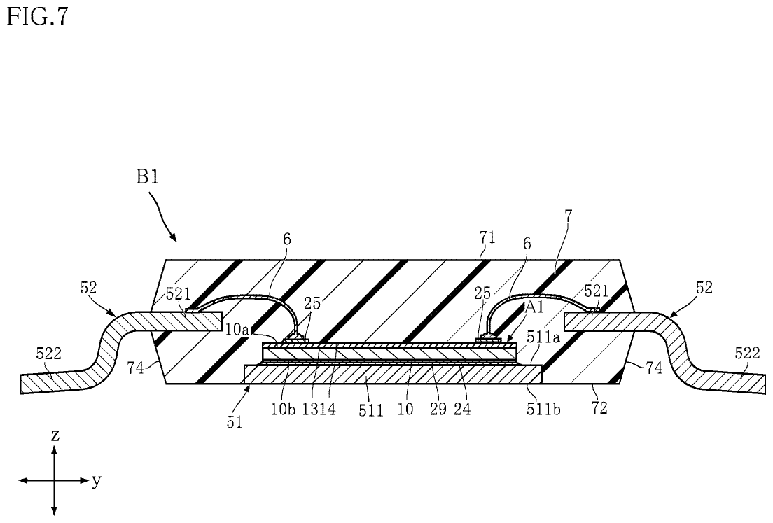

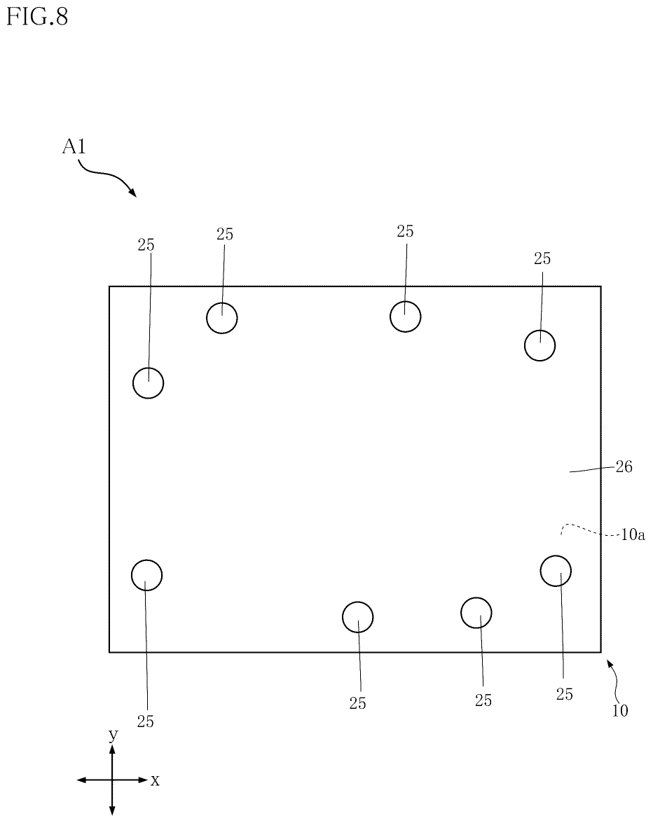

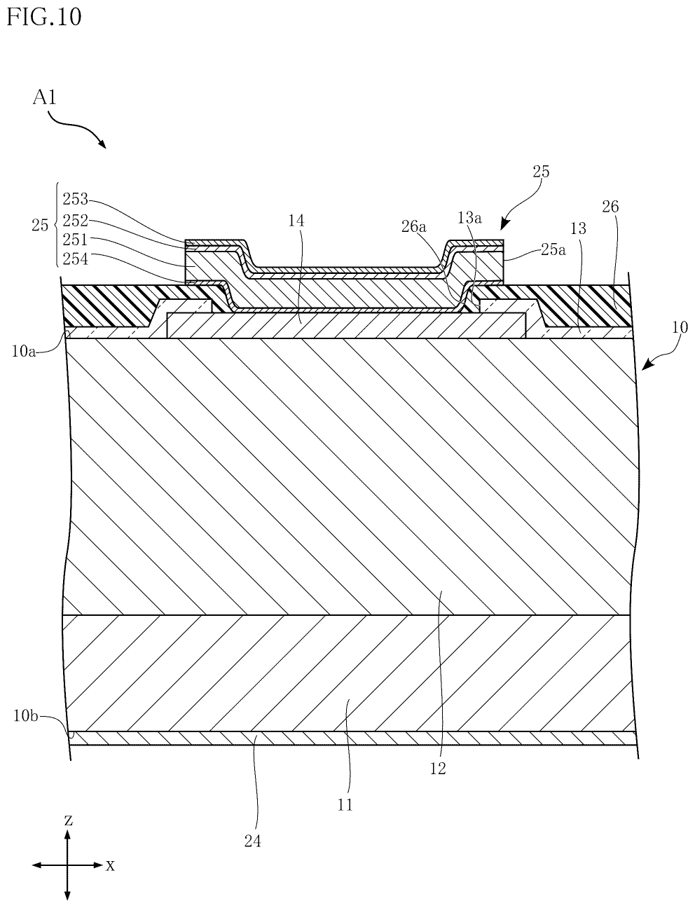

As shown in FIGS. 2 and 8, the element body 10 has a rectangular shape in plan view. As shown in FIGS. 6 and 7, the element body 10 has an obverse surface 10a and a reverse surface 10b. The obverse surface 10a faces a first side in the thickness direction z. The reverse surface 10b faces the opposite side from the obverse surface 10a. As shown in FIG. 10, the element body 10 includes a semiconductor substrate 11 and a semiconductor layer 12.

The semiconductor substrate 11 supports the semiconductor layer 12. The semiconductor substrate 11 is an n+ semiconductor layer. The semiconductor substrate 11 contains silicon (Si) or silicon carbide (Sic), for example. The semiconductor layer 12 is formed on the semiconductor substrate 11. The semiconductor layer 12 is electrically connected to the semiconductor substrate 11. The surface (the lower surface in FIG. 10) of the semiconductor substrate 11 facing the opposite side from the surface on which the semiconductor layer 12 is formed is the reverse surface 10b of the element body 10. The surface (the upper surface in FIG. 10) of the semiconductor layer 12 facing the opposite side from where the semiconductor substrate 11 is located in the thickness direction z is the obverse surface 10a of the element body 10.

The wiring layer 14 is formed on the obverse surface 10a, and is electrically connected to the semiconductor layer 12 of the element body 10. The wiring layer 14 is made of an alloy (AlCu) of aluminum (Al) and copper (Cu), for example. Note that the material of the wiring layer 14 is not particularly limited, and may be another material containing Al, such as Al or AlSi, or may be another material containing Cu. The wiring layer 14 is formed by sputtering, for example. Note that the method for forming the wiring layer 14 is not particularly limited. The plan-view shape of the wiring layer 14 is not particularly limited, and can be designed appropriately according to the arrangement position of each circuit in the semiconductor layer 12 and the arrangement position of the metal layers 25.

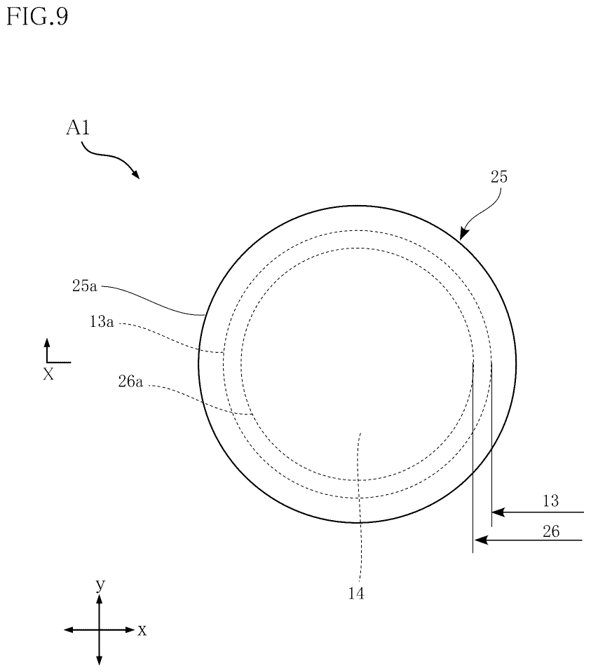

The insulating layer 13 is formed on the obverse surface 10a, and covers the obverse surface 10a and the wiring layer 14. The insulating layer 13 is electrically insulative, and is made of a silicon oxide (SiO₂) film and a silicon nitride (Si₃N₄) film formed on the silicon oxide film, for example. The insulating layer 13 is formed by plasma chemical vapor deposition (CVD), for example. Note that the configuration, material, and formation method of the insulating layer 13 are not particularly limited. The insulating layer 13 has a plurality of openings 13a that pass through the insulating layer 13 in the thickness direction z. The openings 13a expose the wiring layer 14. As shown in FIG. 9, each of the openings 13a in the present embodiment has a circular shape as viewed in the thickness direction z.

FIG. 10 shows only the uppermost wiring layer 14 for simplification, but it is possible to form a plurality of wiring layers 14. In this case, an interlayer insulating layer is provided between the wiring layers 14, and the wiring layers 14 are electrically connected to each other through a via formed in the interlayer insulating layer.

The surface protection film 26 is formed on the obverse surface 10a, and covers the insulating layer 13. In the present embodiment, the surface protection film 26 covers the inner edges of the openings 13a of the insulating layer 13, and is in contact with the wiring layer 14. The surface protection film 26 is electrically insulative, and contains polyimide resin, for example. Note that the material of the surface protection film 26 is not particularly limited, and may be another insulating material. The surface protection film 26 has a plurality of openings 26a that pass through the surface protection film 26 in the thickness direction z. The openings 26a expose the wiring layer 14. As shown in FIG. 9, each of the openings 26a in the present embodiment has a circular shape as viewed in the thickness direction z. In the present embodiment, the openings 26a are enclosed by the respective openings 13a as viewed in the thickness direction z. The surface protection film 26 is formed by applying a photosensitive resin material with a spin coater, followed by photolithography, for example. Note that the method for forming the surface protection film 26 is not particularly limited.

The metal layers 25 are formed on the wiring layer 14 and in contact with the wiring layer 14 via the openings 13a and the openings 26a. Each of the metal layers 25 is electrically connected to an internal circuit of the semiconductor layer 12 via the wiring layer 14. As viewed in the thickness direction z, each of the metal layers 25 overlaps with a portion of the surface protection film 26. As shown in FIG. 2, the metal layers 25 function as pads to which the connecting members 6 are bonded. Each of the metal layers 25 is provided to prevent problems that may occur when a bonding wire is directly bonded to the wiring layer 14, and such problems may be cracks in the element body 10, corrosion at the boundary between the wiring layer 14 and the bonding wire, and a bonding failure of the bonding wire, for example.

As shown in FIG. 10, each of the metal layers 25 is made up of a plurality of metal layers stacked upward from the wiring layer 14, and includes a first layer 251, a second layer 252, a third layer 253, and an underlying layer 254. The underlying layer 254 is in contact with the wiring layer 14, and serves as a conductive path for forming the first layer 251, the second layer 252, and the third layer 253 through electroplating. The underlying layer 254 includes a Ti layer in contact with the wiring layer 14, and a Cu layer in contact with the Ti layer. The underlying layer 254 is formed by sputtering. Note that the material and formation method of the underlying layer 254 are not particularly limited.

The first layer 251 is in contact with the underlying layer 254 and contains Ni. The second layer 252 is in contact with the first layer 251 and contains Pd. The third layer 253 is in contact with the second layer 252 and contains Au. The first layer 251, the second layer 252, and the third layer 253 are formed by electroplating. Note that the configuration, material, and formation method of each metal layer 25 are not particularly limited. For example, the metal layers 25 may not include any third layers 253.

As shown in FIG. 9, each of the metal layers 25 in the present embodiment has a circular shape as viewed in the thickness direction z. In the present embodiment, the openings 13a and the openings 26a are enclosed by the respective metal layers 25 as viewed in the thickness direction z. In other words, the inner edge of each opening 13a and the inner edge of each opening 26a are located inside an outer edge 25a of a metal layer 25 as viewed in the thickness direction z. Note that the inner edge of each opening 13a may be located outside the outer edge 25a of a metal layer 25.

As shown in FIGS. 6, 7, and 10, the reverse-surface electrode 24 is provided on the reverse surface 10b of the element body 10. The reverse-surface electrode 24 is provided over the entirety of the reverse surface 10b. The reverse-surface electrode 24 is electrically connected to the semiconductor layer 12 via the semiconductor substrate 11. The material and configuration of the reverse-surface electrode 24 are not particularly limited. For example, the reverse-surface electrode 24 includes a layer containing silver (Ag) and in contact with the semiconductor substrate 11 and a layer containing gold (Au) and formed on the Ag layer. As shown in FIGS. 6 and 7, the reverse-surface electrode 24 is bonded to the first lead 51 via a conductive bonding member 29. The material of the conductive bonding member 29 may be, but not limited to, solder, silver paste, or sintered silver.

The first lead 51 and the second leads 52 (hereinafter, also collectively referred to as a “conductive support member 5) support the semiconductor element A1 and serve as terminals used to mount the semiconductor device B1 onto a wiring board. The conductive support member 5 is formed by etching or stamping a metal plate, for example. The conductive support member 5 is made of a metal selected from Cu, Ni, iron (Fe), etc., or an alloy of Cu, Ni, or iron (Fe), for example. An appropriate portion of the conductive support member 5 may be plated with a metal selected from Ag, Ni, Pd, Au, etc. The thickness of the conductive support member 5 is not particularly limited, and may be 0.12 mm to 0.2 mm.

The first lead 51 supports the semiconductor element A1. The first lead 51 is electrically connected to the reverse-surface electrode 24 of the semiconductor element A1 via the conductive bonding member 29. As shown in FIGS. 2, 6, and 7, the first lead 51 has a die pad portion 511 and two extending portions 512.

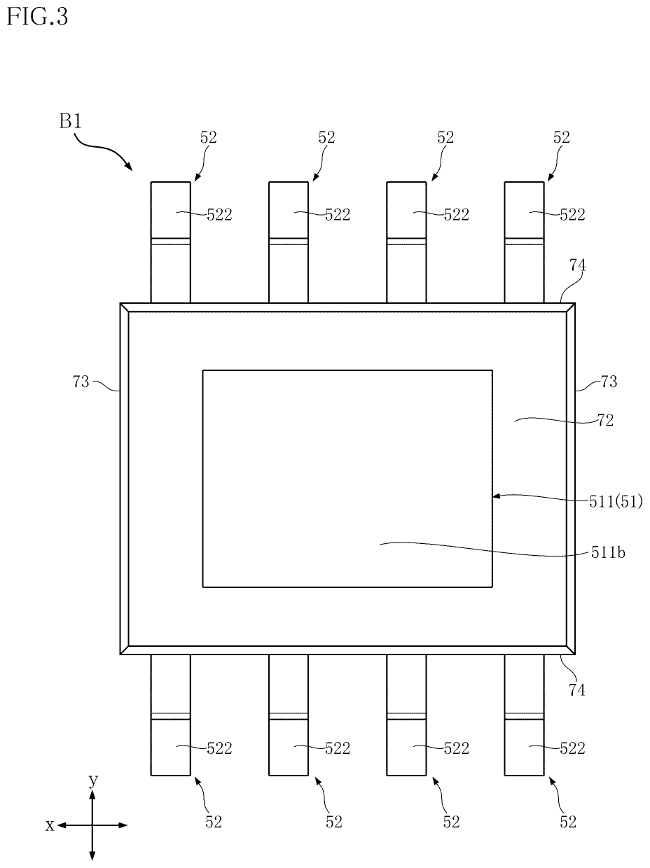

The die pad portion 511 supports the semiconductor element A1. The shape of the die pad portion 511 is not particularly limited. In the example shown in FIG. 2, the die pad portion 511 has a rectangular shape in plan view. As shown in FIGS. 6 and 7, the die pad portion 511 has a die-pad obverse surface 511a and a die-pad reverse surface 511b. The die-pad obverse surface 511a faces the first side in the thickness direction z. The die-pad reverse surface 511b faces away from the die-pad obverse surface 511a in the thickness direction z. In the illustrated example, the die-pad obverse surface 511a and the die-pad reverse surface 511b are flat surfaces. The semiconductor element A1 is bonded to the die-pad obverse surface 511a. As shown in FIGS. 3, 6, and 7, the die-pad reverse surface 511b is exposed from the sealing resin 7 (a resin reverse surface 72 described below).

As shown in FIGS. 2 and 6, the two extending portions 512 extend from the die pad portion 511 to the respective sides in the first direction x. In the example shown in FIG. 6, each of the extending portions 512 has a first section extending from the die pad portion 511 in the first direction x, a second section inclined relative to the first section and extending to the side in the thickness direction z that the die-pad obverse surface 511a faces, and a third section extending from the second section in the first direction x, so that the extending portion 512 has a bent shape as a whole.

As shown in FIG. 2, the second leads 52 are spaced apart from the first lead 51. The second leads 52 are arranged around the first lead 51. In the illustrated example, the second leads 52 include those arranged on a first side in the second direction y with respect to the first lead 51, and those arranged on a second side in the second direction y with respect to the first lead 51. The second leads 52 on each of the first side and the second side in the second direction y are spaced apart from each other in the first direction x. As shown in FIGS. 2 and 6, each of the second leads 52 has a pad portion 521 and a terminal portion 522.

One of the connecting members 6 is connected to the pad portion 521. In the example shown in FIG. 7, the pad portion 521 is offset from the die pad portion 511 to the side in the thickness direction z that the die-pad obverse surface 511a faces.

The terminal portion 522 extends outward from the pad portion 521 in the second direction y. The terminal portion 522 has a strip shape in plan view. As shown in FIG. 7, the terminal portion 522 is bent into a gull-wing shape as viewed in the first direction x. As shown in FIG. 7, a tip (a distal end far from the die pad portion 511 in the second direction y) of the terminal portion 522 is located at substantially the same position as the die pad portion 511 in the thickness direction z.

The terminal portions 522 of the second leads 52 are used as external terminals of the semiconductor device B1. The external terminals include an input terminal for a control signal, a ground terminal, an output terminal connected to a load, a power supply terminal, a non-connected terminal, and a self-diagnostic output terminal.

Each of the connecting members 6 electrically connects two elements that are spaced apart from each other. The connecting members 6 may be, but not limited to, bonding wires. The connecting members 6 contain Cu, for example. The material of the connecting members 6 is not particularly limited, and the connecting members 6 may contain Al or Au.

Each of the connecting members 6 is bonded to one of the metal layers 25 (pads) of the semiconductor element A1 and one of the pad portions 521 of the second leads 52. Each of the connecting members 6 electrically connects an internal circuit in the semiconductor element A1 and a second lead 52.

The sealing resin 7 covers a portion of each of the first lead 51 and the second leads 52, the semiconductor element A1, and the connecting members 6. The sealing resin 7 is an insulating resin, and may contain an epoxy resin mixed with a filler. The sealing resin 7 has a resin obverse surface 71, a resin reverse surface 72, two resin side surfaces 73, and two resin side surfaces 74.

The resin obverse surface 71 faces the same side as the die-pad obverse surface 511a in the thickness direction z. The resin obverse surface 71 is a flat surface, for example. The resin reverse surface 72 faces the opposite side from the resin obverse surface 71 (the same side as the die-pad reverse surface 511b) in the thickness direction z. The resin reverse surface 72 is a flat surface, for example. The die-pad reverse surface 511b is exposed from the resin reverse surface 72.

The two resin side surfaces 73 are located between the resin obverse surface 71 and the resin reverse surface 72 in the thickness direction z, and are spaced apart from each other in the first direction x as shown in FIGS. 2 to 4. Each of the extending portions 512 is exposed from one of the two resin side surfaces 73. The two resin side surfaces 74 are located between the resin obverse surface 71 and the resin reverse surface 72 in the thickness direction z, and are spaced apart from each other in the second direction y as shown in FIGS. 2, 3 and 5. Each of the second leads 52 protrudes from one of the two resin side surfaces 74.

The following describes the advantages of the semiconductor element A1 and the semiconductor device B1.

The semiconductor element A1 includes the surface protection film 26 and the metal layers 25 formed on the obverse surface 10a. As viewed in the thickness direction z, each of the metal layers 25 overlaps with a portion of the surface protection film 26. The metal layers 25 and the surface protection film 26 have different coefficients of thermal expansion due to the difference in material, and thus thermal stress is applied to the surface protection film 26. Since the metal layer of a conventional semiconductor element has a rectangular shape as viewed in the thickness direction z, thermal stress is concentrated at the positions of the surface protection film 26 that overlap with the corners of the metal layer as viewed in the thickness direction z, thus easily causing cracks. However, in the semiconductor element A1, each metal layer 25 has a circular shape as viewed in the thickness direction z, which allows thermal stress to be dispersed and not concentrated in a particular area. Thus, the semiconductor element A1 can suppress the occurrence of cracks in the surface protection film 26, as compared to when the shape of each metal layer 25 is rectangular as viewed in the thickness direction z.

Furthermore, in the semiconductor element A1, the openings 26a of the surface protection film 26 are enclosed by the respective openings 13a of the insulating layer 13 as viewed in the thickness direction z. In contrast, if the openings 13a are enclosed by the openings 26a, cracks are likely to be formed in the insulating layer 13 at the positions overlapping with the openings 26a of the surface protection film 26 as viewed in the thickness direction z due to the thermal stress caused by the difference in coefficient of thermal expansion between the surface protection film 26 and the insulating layer 13. In the semiconductor element A1, however, the openings 26a are enclosed by the openings 13a to suppress the occurrence of cracks in the insulating layer 13. Furthermore, although the surface protection film 26 is subjected to thermal stress due to the difference in coefficient of thermal expansion between the insulating layer 13 and the surface protection film 26, the thermal stress is dispersed and not concentrated in a particular area because the openings 13a each have a circular shape as viewed in the thickness direction z. Thus, the semiconductor element A1 can suppress the occurrence of cracks in the surface protection film 26, as compared to when the shape of each opening 13a is rectangular as viewed in the thickness direction z.

Furthermore, in the semiconductor element A1, the openings 26a of the surface protection film 26 as viewed in the thickness direction z each have a circular shape similar to the shape of each opening 13a of the insulating layer 13. This allows the semiconductor element A1 to increase the contact area in which the metal layers 25 make contact with the wiring layer 14 as compared to when the openings 26a each have a different shape such as a rectangular shape.

The semiconductor device B1 includes the semiconductor element A1. The semiconductor device B1 undergoes frequent temperature changes depending on its use environment. For example, when the semiconductor device B1 is mounted on a circuit board of an automobile or the like, the automobile may run under various climatic conditions from cold to hot and humid areas. Furthermore, when the semiconductor device B1 is mounted within the engine room, it will be constantly exposed to temperature changes resulting from the environment and driving patterns. Since the semiconductor element A1 can suppress the occurrence of cracks resulting from temperature changes as described above, the semiconductor device B1 has improved reliability on temperature changes. This allows the use of the semiconductor device B1 even in an environment with frequent temperature changes, and the semiconductor device B1 is therefore applicable to a wide range of uses.

Although the present embodiment has been described with an example where the metal layers 25, the openings 13a, and the openings 26a each have a circular shape as viewed in the thickness direction z, the present disclosure is not limited to this. The shape of each metal layer 25 as viewed in the thickness direction z may be another shape, such as an elliptical shape, with the outer edge 25a formed by a curve so that the metal layer 25 does not include any portions at which stress is concentrated. Although the shape of each opening 13a as viewed in the thickness direction z is preferably a shape with the inner edge formed by a curve so that the opening 13a does not include any portions at which stress is concentrated, the opening 13a may have another shape. Although the shape of each opening 26a as viewed in the thickness direction z is preferably a shape with the inner edge formed by a curve so that the opening 26a does not include any portions at which stress is concentrated, the opening 26a may have another shape. Furthermore, the metal layers 25, the openings 13a, and the openings 26a preferably have similar shapes as viewed in the thickness direction z, but they may not have similar shapes.

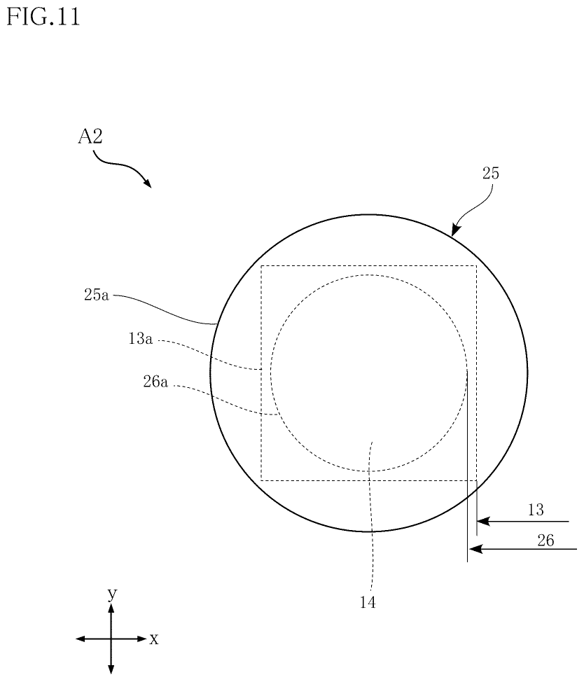

FIGS. 11 to 16 show other embodiments of the present disclosure. In these figures, elements that are the same as or similar to those in the above embodiment are provided with the same reference numerals as in the above embodiment.

### Second Embodiment

FIG. 11 is a view for describing a semiconductor element A2 according to a second embodiment of the present disclosure. FIG. 11 is a partially enlarged plan view showing the semiconductor element A2, and corresponds to FIG. 9. The semiconductor element A2 in the present embodiment is different from the semiconductor element in the first embodiment in that the openings 13a of the insulating layer 13 each have a rectangular shape as viewed in the thickness direction z. The configurations and operations of other parts of the present embodiment are the same as those of the first embodiment.

In the present embodiment, the shape of each metal layer 25 is circular as viewed in the thickness direction z, and therefore the thermal stress applied to the surface protection film 26 is dispersed and not concentrated in a particular area. Thus, the semiconductor element A2 can suppress the occurrence of cracks in the surface protection film 26, as compared to when the shape of each metal layer 25 is rectangular as viewed in the thickness direction z. Furthermore, in the semiconductor element A2, the openings 26a of the surface protection film 26 are enclosed by the respective openings 13a of the insulating layer 13 as viewed in the thickness direction z, thereby suppressing the occurrence of cracks in the insulating layer 13.

### Third Embodiment

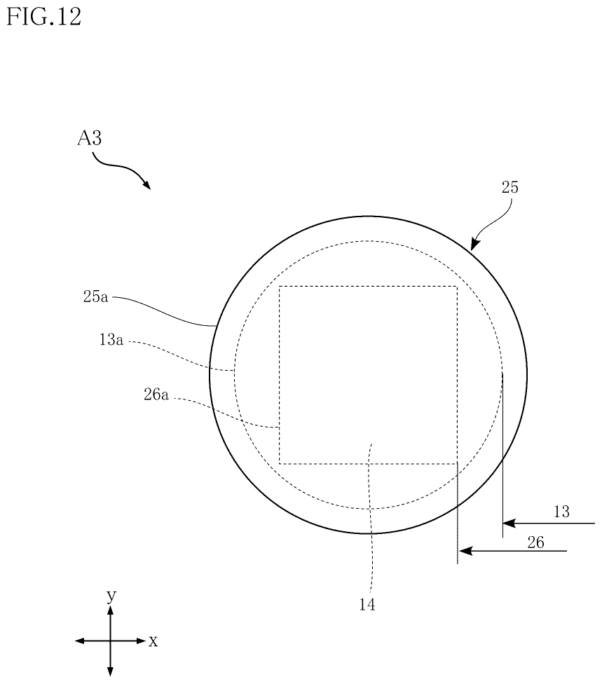

FIG. 12 is a view for describing a semiconductor element A3 according to a third embodiment of the present disclosure. FIG. 12 is a partially enlarged plan view showing the semiconductor element A3, and corresponds to FIG. 9. The semiconductor element A3 in the present embodiment is different from the semiconductor element in the first embodiment in that each of the openings 26a has a rectangular shape as viewed in the thickness direction z. The configurations and operations of other parts of the present embodiment are the same as those of the first embodiment. The present embodiment may be combined with any part of the first to second embodiments.

In the present embodiment, the shape of each metal layer 25 is circular as viewed in the thickness direction z, and therefore the thermal stress applied to the surface protection film 26 is dispersed and not concentrated in a particular area. Thus, the semiconductor element A3 can suppress the occurrence of cracks in the surface protection film 26, as compared to when the shape of each metal layer 25 is rectangular as viewed in the thickness direction z. Furthermore, in the semiconductor element A3, the openings 26a of the surface protection film 26 are enclosed by the respective openings 13a of the insulating layer 13 as viewed in the thickness direction z, thereby suppressing the occurrence of cracks in the insulating layer 13. Furthermore, since each of the openings 13a has a circular shape as viewed in the thickness direction z, thermal stress is dispersed and not concentrated in a particular area. Thus, the semiconductor element A3 can suppress the occurrence of cracks in the surface protection film 26, as compared to when the shape of each opening 13a is rectangular as viewed in the thickness direction z.

### Fourth Embodiment

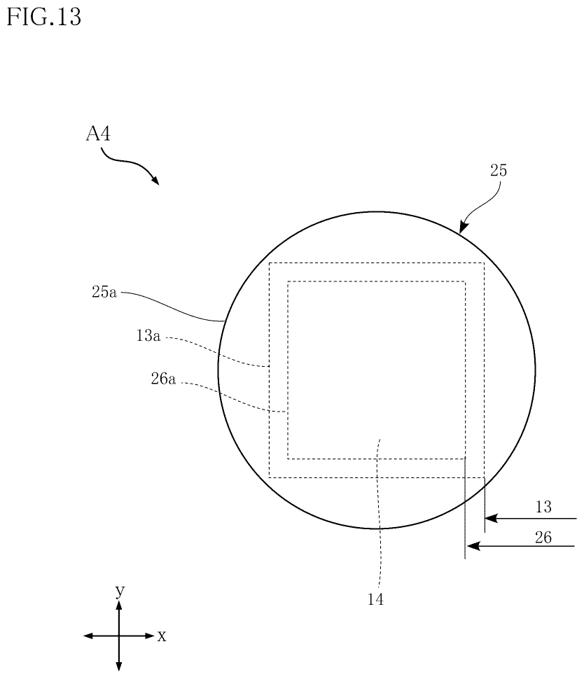

FIG. 13 is a view for describing a semiconductor element A4 according to a fourth embodiment of the present disclosure. FIG. 13 is a partially enlarged plan view showing the semiconductor element A4, and corresponds to FIG. 9. The semiconductor element A4 in the present embodiment is different from the semiconductor element in the first embodiment in that each of the openings 13a and the openings 26a has a rectangular shape as viewed in the thickness direction z. The configurations and operations of other parts of the present embodiment are the same as those of the first embodiment. The present embodiment may be combined with any part of the first to third embodiments.

In the present embodiment, the shape of each metal layer 25 is circular as viewed in the thickness direction z, and therefore the thermal stress applied to the surface protection film 26 is dispersed and not concentrated in a particular area. Thus, the semiconductor element A4 can suppress the occurrence of cracks in the surface protection film 26, as compared to when the shape of each metal layer 25 is rectangular as viewed in the thickness direction z. Furthermore, in the semiconductor element A4, the openings 26a of the surface protection film 26 are enclosed by the respective openings 13a of the insulating layer 13 as viewed in the thickness direction z, thereby suppressing the occurrence of cracks in the insulating layer 13.

### Fifth Embodiment

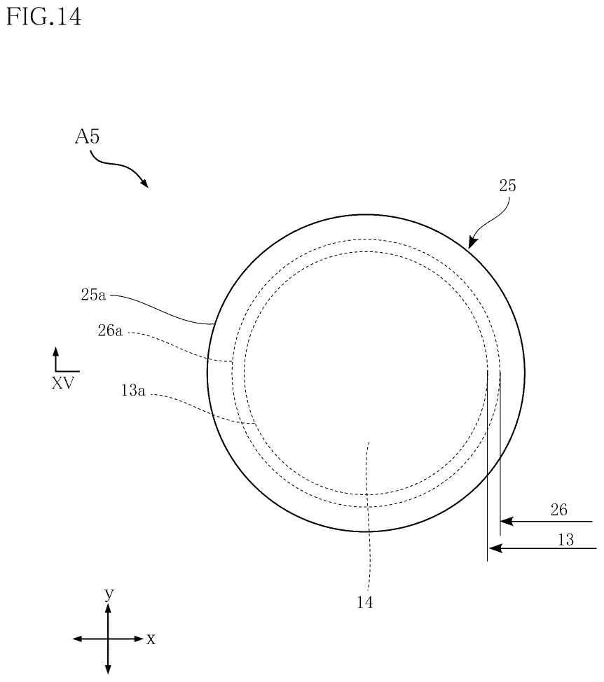

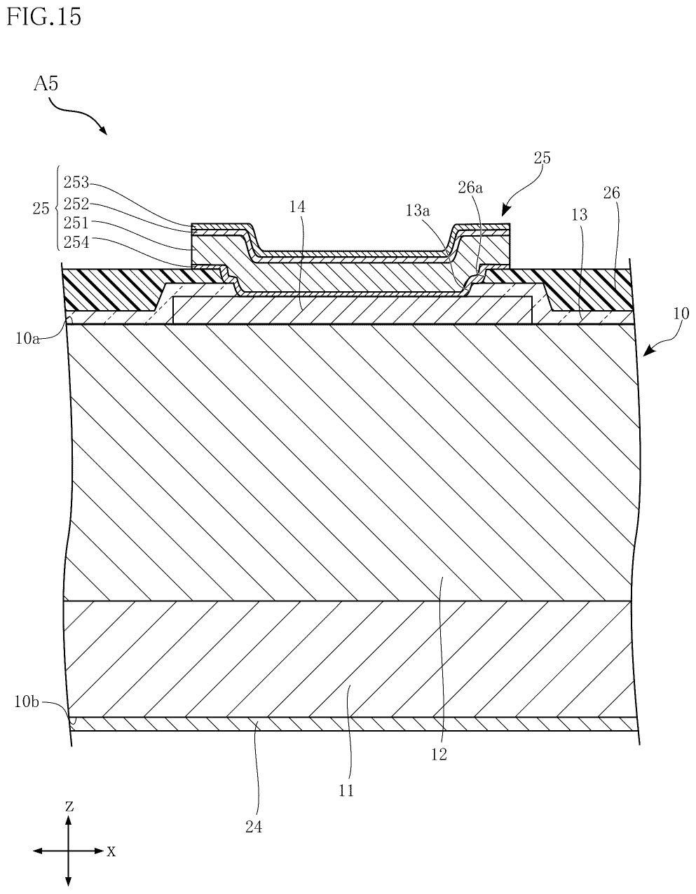

FIGS. 14 and 15 are views for describing a semiconductor element A5 according to a fifth embodiment of the present disclosure. FIG. 14 is a partially enlarged plan view showing the semiconductor element A5, and corresponds to FIG. 9. FIG. 15 is a cross-sectional view along line XV-XV in FIG. 14, and corresponds to FIG. 10. The semiconductor element A5 in the present embodiment is different from the semiconductor element in the first embodiment in that the openings 13a are enclosed by the openings 26a as viewed in the thickness direction z. The configurations and operations of other parts of the present embodiment are the same as those of the first embodiment. The present embodiment may be combined with any part of the first to fourth embodiments.

In the present embodiment, the shape of each metal layer 25 is circular as viewed in the thickness direction z, and therefore the thermal stress applied to the surface protection film 26 is dispersed and not concentrated in a particular area. Thus, the semiconductor element A5 can suppress the occurrence of cracks in the surface protection film 26, as compared to when the shape of each metal layer 25 is rectangular as viewed in the thickness direction z. In the present embodiment, the openings 13a of the insulating layer 13 are enclosed by the respective openings 26a of the surface protection film 26 as viewed in the thickness direction z, thereby suppressing the occurrence of cracks in the surface protection film 26. Furthermore, although the openings 13a are enclosed by the openings 26a, stress is dispersed and not concentrated in a particular area since the openings 26a are circular as viewed in the thickness direction z. Thus, the semiconductor element A5 can suppress the occurrence of cracks in the insulating layer 13, as compared to when the shape of each opening 26a is rectangular as viewed in the thickness direction z. Furthermore, in the semiconductor element A5, the openings 13a of the insulating layer 13 as viewed in the thickness direction z each have a circular shape similar to the shape of each opening 26a of the surface protection film 26. This allows the semiconductor element A5 to increase the contact area in which the metal layers 25 make contact with the wiring layer 14 as compared to when the openings 13a each have a rectangular shape.

### Sixth Embodiment

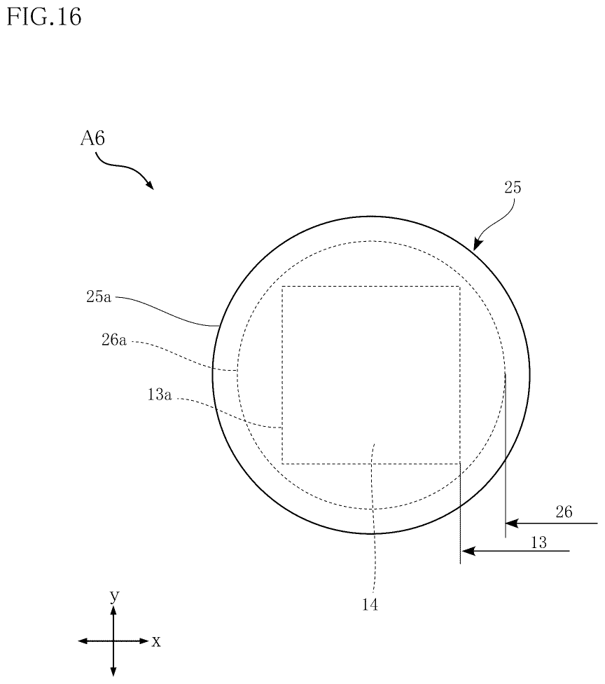

FIG. 16 is a view for describing a semiconductor element A6 according to a sixth embodiment of the present disclosure. FIG. 16 is a partially enlarged plan view showing the semiconductor element A6, and corresponds to FIG. 9. The semiconductor element A6 in the present embodiment is different from the semiconductor element in the fifth embodiment in that each of the openings 13a has a rectangular shape as viewed in the thickness direction z. The configurations and operations of other parts of the present embodiment are the same as those of the fifth embodiment. The present embodiment may be combined with any part of the first to fifth embodiments.

In the present embodiment, the shape of each metal layer 25 is circular as viewed in the thickness direction z, and therefore the thermal stress applied to the surface protection film 26 is dispersed and not concentrated in a particular area. Thus, the semiconductor element A6 can suppress the occurrence of cracks in the surface protection film 26, as compared to when the shape of each metal layer 25 is rectangular as viewed in the thickness direction z. In the present embodiment, the openings 13a of the insulating layer 13 are enclosed by the respective openings 26a of the surface protection film 26 as viewed in the thickness direction z, thereby suppressing the occurrence of cracks in the surface protection film 26. Furthermore, although the openings 13a are enclosed by the openings 26a, stress is dispersed and not concentrated in a particular area since the openings 26a are circular as viewed in the thickness direction z. Thus, the semiconductor element A6 can suppress the occurrence of cracks in the insulating layer 13, as compared to when the shape of each opening 26a is rectangular as viewed in the thickness direction z.

Although the first to sixth embodiments have been described with an example where the semiconductor elements A1 to A6 are LSIs, the present disclosure is not limited to this. The semiconductor elements A1 to A6 may be discrete semiconductor elements. Furthermore, the mode (type) of the semiconductor device B1 is not limited.

The semiconductor element and the semiconductor device according to the present disclosure are not limited to the above embodiments. Various design changes can be made to the specific configurations of the components in the semiconductor element and the semiconductor device according to the present disclosure. The present disclosure includes the embodiments described in the following clauses.

### Clause 1.

A semiconductor element (A1) comprising:
an element body (10) including an element obverse surface (10a) facing a first side in a thickness direction;
a wiring layer (14) formed on the element obverse surface and electrically connected to the element body;
an insulating layer (13) covering the element obverse surface and the wiring layer, and including a first opening (13a) through which the wiring layer is exposed;
a surface protection film (26) covering the insulating layer, and including a second opening (26a) through which the wiring layer is exposed; and
a metal layer (25) in contact with the wiring layer via the first opening and the second opening, and overlapping with the surface protection film as viewed in the thickness direction,
wherein an outer edge (25a) of the metal layer is curved as viewed in the thickness direction.

### Clause 2.

The semiconductor element according to clause 1, wherein the metal layer has a circular shape as viewed in the thickness direction.

### Clause 3.

The semiconductor element according to clause 1 or 2, wherein an inner edge of the first opening is curved as viewed in the thickness direction.

### Clause 4.

The semiconductor element according to clause 3, wherein a shape of the first opening is similar to a shape of the metal layer as viewed in the thickness direction.

### Clause 5.

The semiconductor element according to any of clauses 1 to 4, wherein an inner edge of the second opening is curved as viewed in the thickness direction.

### Clause 6.

The semiconductor element according to clause 5, wherein a shape of the second opening is similar to the shape of the metal layer as viewed in the thickness direction.

### Clause 7.

The semiconductor element according to any of clauses 1 to 6, wherein the second opening is enclosed by the first opening as viewed in the thickness direction.

### Clause 8.

The semiconductor element according to any of clauses 1 to 7, wherein the metal layer includes:
a first layer (251) containing Ni; and
a second layer (252) in contact with a surface of the first layer on a side that the element obverse surface faces, and containing Pd.

### Clause 9.

The semiconductor element according to clause 8, wherein the metal layer further includes a third layer (253) in contact with a surface of the second layer on the side that the element obverse surface faces, and containing Au.

### Clause 10.

The semiconductor element according to clause 8 or 9, wherein the metal layer further includes a fourth layer (254) provided between the first layer and the wiring layer.

### Clause 11.

The semiconductor element according to any of clauses 1 to 10, wherein the surface protection film contains polyimide resin.

### Clause 12.

The semiconductor element according to any of clauses 1 to 11, wherein the wiring layer contains Al.

### Clause 13.

The semiconductor element according to any of clauses 1 to 12, further comprising a reverse-surface electrode (24) electrically connected to the element body,
wherein the element body further includes an element reverse surface (10b) facing away from the element obverse surface in the thickness direction, and
the reverse-surface electrode is arranged on the element reverse surface.

### Clause 14.

A semiconductor device (B1), comprising:
the semiconductor element according to any of clauses 1 to 13;
a conductive support member (5) supporting the semiconductor element and electrically connected to the semiconductor element;
a connecting member (6) bonded to the metal layer of the semiconductor element and the conductive support member; and
a sealing resin (7) covering the semiconductor element, the connecting member, and a portion of the conductive support member.

### Clause 15.

The semiconductor device according to clause 14, wherein the connecting member is a bonding wire containing Cu.

REFERENCE NUMERALS

| | |
|---|---|
| A1 to A6: Semiconductor element | B1: Semiconductor device |
| 10: Element body | 10a: Obverse surface |
| 10b: Reverse surface | 11: Semiconductor substrate |
| 12: Semiconductor layer | 13: Insulating layer |
| 13a: Opening | 14: Wiring layer |
| 24: Reverse-surface electrode | 25: Metal layer |
| 25a: Outer edge | 251: First layer |
| 252: Second layer | 253: Third layer |
| 254: Underlying layer | 26: Surface protection film |
| 26a: Opening | 29: Conductive bonding member |
| 5: Conductive support member | 51: First lead |
| 511: Die pad portion | 511a: Die-pad obverse surface |
| 511b: Die-pad reverse surface | 512: Extending portion |
| 52: Second lead | 521: Pad portion |
| 522: Terminal portion | 6: Connecting member |
| 7: Sealing resin | 71: Resin obverse surface |
| 72: Resin reverse surface | 73: Resin side surface |
| 74: Resin side surface | |

1. A semiconductor element comprising:
an element body including an element obverse surface facing a first side in a thickness direction;
a wiring layer formed on the element obverse surface and electrically connected to the element body;
an insulating layer covering the element obverse surface and the wiring layer, and including a first opening through which the wiring layer is exposed;
a surface protection film covering the insulating layer, and including a second opening through which the wiring layer is exposed; and
a metal layer in contact with the wiring layer via the first opening and the second opening, and overlapping with the surface protection film as viewed in the thickness direction,
wherein an outer edge of the metal layer is curved as viewed in the thickness direction.

2. The semiconductor element according to claim 1, wherein the metal layer has a circular shape as viewed in the thickness direction.

3. The semiconductor element according to claim 1, wherein an inner edge of the first opening is curved as viewed in the thickness direction.

4. The semiconductor element according to claim 3, wherein a shape of the first opening is similar to a shape of the metal layer as viewed in the thickness direction.

5. The semiconductor element according to claim 1, wherein an inner edge of the second opening is curved as viewed in the thickness direction.

6. The semiconductor element according to claim 5, wherein a shape of the second opening is similar to the shape of the metal layer as viewed in the thickness direction.

7. The semiconductor element according to claim 1, wherein the second opening is enclosed by the first opening as viewed in the thickness direction.

8. The semiconductor element according to claim 1, wherein the metal layer includes:
a first layer containing Ni; and
a second layer in contact with a surface of the first layer on a side that the element obverse surface faces, and containing Pd.

9. The semiconductor element according to claim 8, wherein the metal layer further includes a third layer in contact with a surface of the second layer on the side that the element obverse surface faces, and containing Au.

10. The semiconductor element according to claim 8, wherein the metal layer further includes a fourth layer provided between the first layer and the wiring layer.

11. The semiconductor element according to claim 1, wherein the surface protection film contains polyimide resin.

12. The semiconductor element according to claim 1, wherein the wiring layer contains Al.

13. The semiconductor element according to claim 1, further comprising a reverse-surface electrode electrically connected to the element body,
wherein the element body further includes an element reverse surface facing away from the element obverse surface in the thickness direction, and
the reverse-surface electrode is arranged on the element reverse surface.

14. A semiconductor device, comprising:
the semiconductor element according to claim 1;
a conductive support member supporting the semiconductor element and electrically connected to the semiconductor element;
a connecting member bonded to the metal layer of the semiconductor element and the conductive support member; and
a sealing resin covering the semiconductor element, the connecting member, and a portion of the conductive support member.

15. The semiconductor device according to claim 14, wherein the connecting member is a bonding wire containing Cu.
